(19) United States
(12) Patent Application Publication
(10) Pub. No.: US 2010/0037941 A1
(43) Pub. Date: Feb. 18, 2010

(54) COMPOSITIONS AND PROCESSES FOR FORMING PHOTOVOLTAIC DEVICES

(75) Inventors: WILLIAM J. BORLAND, Chapel Hill, NC (US); Jon-Paul Maria, Raleigh, NC (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignees: E. I. DU PONT DE NEMOURS AND COMPANY, Wilmington, DE (US); NORTH CAROLINA STATE UNIVERSITY, Raleigh, NC (US)

(21) Appl. No.: 12/536,227

(22) Filed: Aug. 5, 2009

Related U.S. Application Data
(60) Provisional application No. 61/088,473, filed on Aug. 13, 2008.

(51) Int. Cl. H01L 31/07; H01L 31/00; H01L 31/0232; H01L 31/028; H01B 1/22

(52) U.S. Cl. 136/255; 438/92; 438/72; 136/261; 252/513; 252/515; 252/514; 977/773; 257/E31.127; 257/E31.001

(57) ABSTRACT

Methods and compositions for making photovoltaic devices are provided. A metal that is reactive with silicon is placed in contact with the n-type silicon layer of a silicon substrate. The silicon substrate and reactive metal are fired to form a silicide contact to the n-type silicon layer. A conductive metal electrode is placed in contact with the silicide contact. A silicon solar cell made by such methods is also provided.

### FIELD OF THE INVENTION

This invention is directed to photovoltaic devices, such as solar cells, light emitting diodes, and photodetectors. In particular, it is directed to compositions and processes for use in forming front face electrical contacts to the n-type silicon of a solar cell device.

### BACKGROUND OF THE INVENTION

The present invention can be applied to a range of semiconductor devices, although it is especially effective in light-receiving elements such as photodetectors and solar cells. The background of the invention is described below with reference to solar cells as a specific example of the prior art.

Conventional terrestrial solar cells are generally made of thin wafers of silicon (Si) in which a rectifying or p-n junction has been created and electrode contacts, that are electrically conductive, have been subsequently formed on both sides of the wafer. A solar cell structure with a p-type silicon base has a positive electrode contact on the base or backside and a negative electrode contact on the n-type silicon or emitter that is the front-side or sun-illuminated side of the cell. The “emitter” is a layer of silicon that is doped in order to create the rectifying or p-n junction and is thin in comparison to the p-type silicon base. It is well-known that radiation of an appropriate wavelength incident on a p-n junction of a semiconductor body serves as a source of external energy to generate hole-electron pairs in that body. Because of the potential difference which exists at a p-n junction, holes and electrons move across the junction in opposite directions. The electrons move to the negative electrode contact, and the holes move to positive electrode contact, thereby giving rise to flow of an electric current that is capable of delivering power to an external circuit. The electrode contacts to the solar cell are important to the performance of the cell. A high resistance silicon/electrode contact interface will impede the transfer of current from the cell to the external electrodes and therefore, reduce efficiency.

Most industrial crystalline silicon solar cells are fabricated with a silicon nitride anti-reflective coating (ARC) on the front-side to maximize sunlight absorption. As disclosed in a number of publications, such as US Patent Application US 2006/0231801 to Carroll et al., front side electrode contacts are generally made by screen printing a conductive paste on the anti-reflective coating following by firing at an elevated temperature. The conductive paste typically includes a silver powder, a glass fritt, an organic medium, and one or more additives. During firing, the conductive paste sinters and penetrates through the silicon nitride film and is thereby able to electrically contact the n-type silicon layer. This type of process is generally called “fire through” or “etching” of the silicon nitride. It is generally accepted that the contact formation of screen printed silver pastes to the front face of solar cells involves a complex series of interactions between the glass, silver, silicon nitride and silicon. The sequence and rates of reactions occurring during the firing process are factors in forming the contact between the silver paste and the silicon. The interface structure after firing consists of multiple phases: substrate silicon; silver-silicon islands; silver precipitates within an insulating glass layer; and bulk sintered silver. As a result, the contact mechanism is a mix of ohmic contact by the silver-silicon islands and silver precipitates and tunneling through thin layers of the glass. The extent of each of these components of the structure depends on many factors such as the glass composition, the amount of glass in the composition and the temperature of firing. Compositions and firing profiles of the conductive paste are optimized to maximize cell efficiency. However, the presence of glass at the metal-silicon interface inevitably results in a higher contact resistance than would be realized by a pure metal contact to silicon.

Difficulties associated with forming low resistance contacts to bipolar silicon devices exist. All elemental semiconductor contacts have a potential barrier that makes the contact rectifying. A Shottky barrier height (SBH) is the rectifying barrier for electrical conduction across a metal-silicon (MS) interface and, therefore, is of vital importance to the successful operation of any semiconductor device. The magnitude of the SBH reflects the mismatch in the energy position of the majority carrier band edge of the semiconductor and the metal Fermi level across the MS interface. At a metal/n-type semiconductor interface, the SBH is the difference between the conduction band minimum and the Fermi level. The lower the SBH, the better the contact to silicon. Low Shottky barrier height contacts to n-type silicon semiconductor devices are known. U.S. Pat. Nos. 3,381,182, 3,968,272 and 4,394,673, for example, disclose various silicides that form low SBH contacts to bipolar silicon devices when the metal is placed in contact with the silicon and heated. Such silicide contacts have not been used as front face electrode contacts to silicon solar cells.

Another method of fabrication of a silicon solar cell is to locally remove the silicon nitride ARC prior to deposition of the front electrode contacts. Such a method is designed to allow metal deposition directly on to the n-type silicon to improve the contact resistance at the metal-silicon interface and is described with reference to FIG. 1.

In FIG. 1A, a p-type silicon substrate 10 is provided. The substrate may be composed of single-crystal silicon or of multicrystalline silicon. As shown in FIG. 1B, in the case of a p-type substrate, an n-type layer 20 in FIG. 1B, is formed to create a p-n junction. The method used to form the n-type layer is generally by the thermal diffusion of a donor dopant from Group V of the periodic table, preferably phosphorus (P), using phosphorus oxychloride (POCl₃). In the absence of any particular modification, the diffusion layer 20 is formed over the entire surface of the silicon substrate 10.

Next, one surface of this diffusion layer is protected with a resist or the like and the diffusion layer 20 is removed from all but the protected surface of the article of FIG. 1B by etching. The resist is removed, leaving the article of FIG. 1C. These steps are not always necessary when a phosphorus-containing liquid coating material such as phosphosilicate glass (PSG) is applied onto only one surface of the substrate by a process, such as spin coating, and diffusion is effected by annealing under suitable conditions.

Next, as shown in FIG. 1D, an insulating silicon nitride Si₃N₄ film, or a silicon nitride SiNx:H film is formed on the above-described n-type diffusion layer to form an anti-reflective coating (ARC). The thickness of the Si₃N₄ or SiNx:H anti-reflective coating 30 is about 700 to 900 Å. As an alternative to the silicon nitride, silicon oxide may be used as an anti-reflection coating.

Next, a photoresist 40 is applied to the entire surface of the anti-reflective coating of the front face. The photoresist 40 is selectively imaged and developed to expose the underlying anti-reflective coating by forming trenches 45 in the photoresist, as shown in FIG. 1E. The trenches are formed so as to correspond to the fingers and bussbars of the front electrode contacts. Typical width of the bussbars and fingers may be in the order of 1.5 mm for the bussbars and 100 micrometers for the fingers although other dimensions may be applied.

The article of FIG. 1E is now subjected to an etchant bath to dissolve the exposed anti-reflective coating. A suitable etchant is hot, dilute phosphoric acid. The etching locally dissolves the anti-reflective coating 30 forming a trench 50, as shown in FIG. 1F, in the anti-reflective coating, which exposes the underlying n-type silicon. Using this technique, an opening in the anti-reflective coating can be achieved without damaging the underlying n-type silicon. The photoresist 40 is now removed to form the article of FIG. 1G.

As shown in FIG. 1H, an aluminum paste 60 and a backside silver or silver/aluminum paste 70 are screen printed and successively dried on the backside of the substrate. Firing of the backside pastes is then carried out in an infrared furnace at a temperature range of approximately 700° C. to 975° C. in air for a period of from several minutes to several tens of minutes.

As shown in FIG. 1J, aluminum diffuses from the aluminum paste into the silicon substrate 10 as a dopant during firing, forming a p+ layer 61 containing a high concentration of aluminum dopant. This layer is generally called the back surface field (BSF) layer, and helps to improve the energy conversion efficiency of the solar cell.

Firing also converts the aluminum paste 60 to an aluminum back electrode 65. The backside silver or silver/aluminum paste 70 (fired at the same time) becomes a silver or silver/aluminum back electrode 71. During firing, the boundary between the back side aluminum and the back side silver or silver/aluminum assumes an alloy state, thereby achieving electricial connection. The aluminum electrode accounts for most areas of the back electrode, owing in part to the need to form a p+ layer 61. Because soldering to an aluminum electrode is impossible, a silver back tab electrode is formed over portions of the back side as an electrode for interconnecting solar cells by means of copper ribbon or the like.

In FIG. 1K, the desired metallization 80 is deposited into the trench 50. Deposition may be undertaken by thin film processes, such as sputtering, chemical vapor deposition, atomic layer deposition, and the like, or by thick film processes, such as screen printing. Deposition is achieved through a mask that conforms to the etched trench pattern. Typical metallization metals deposited are silver and/or nickel. In the case of metallization using a thick film process, the conductive paste normally contains a metal powder, such as silver and a glass component. The thick film paste deposit is subsequently fired to sinter the metal and adhere the metal to the underlying silicon. Firing is not necessary with the thin film deposition process. Fabrication of the front electrode of the silicon solar cell is now complete.

Novel compositions and processes for forming front electrode contacts to silicon solar cells are needed, which provide superior reduction in contact resistance and maintain adhesion.

### SUMMARY OF THE INVENTION

A method for making a photovoltaic device is disclosed. According to the disclosed method, a silicon substrate having an n-type silicon layer is provided. A reactive metal is placed in contact with the n-type silicon layer. The silicon substrate and reactive metal are fired to form a low Shottky barrier height contact to the n-type silicon layer. The low Shottky barrier height contact is comprised of one or more transition metal silicides, rare earth metal silicides, or combinations thereof. In a preferred embodiment, the reactive metal is one or more metals selected from titanium, zirconium, hafnium, vanadium, niobium, tantalum, molybdenum, cobalt, nickel, cerium, dysprosium, erbium, holmium, gadolinium, lanthanum, scandium, yttrium and combinations thereof.

In a preferred embodiment, a non-reactive metal is placed in contact with the reactive metal before firing. Alternatively, the non-reactive metal may be deposited post firing on the silicide formed during firing. The non-reactive metal forms a conductive metal electrode in contact with the low Shottky barrier height contact. Preferred non-reactive metals may be selected from the group of silver, tin, bismuth, indium, lead, antimony, zinc, germanium, phosphorus, gold, cadmium, berrylium, and combinations thereof.

In one preferred method, the reactive metal and the non-reactive metal are combined to form a metals composition that is subsequently deposited on the n-type silicon layer. In one embodiment, the reactive metal is in the form of particles having an average diameter in the range of 100 nanometers to 50 micrometers. The reactive metal preferably forms between 1 and 25 weight percent of the total of the metals composition.

In one preferred embodiment of the method of the invention, the silicon substrate, reactive metal and non-reactive metal are fired at a temperature between 400° C. and 950° C. In a preferred embodiment, the silicon substrate, reactive metal and non-reactive metal are cofired.

In another preferred method, the reactive metal is deposited on the silicon and fired at a temperature between 400° C. and 950° C. to form a metal silicide before the non-reactive metal is deposited. The non-reactive metal may be deposited onto the metal silicide by a variety of means such as plating, thick film deposition or sputtering and the like.

A method for making a silicon solar cell is also disclosed. According to the disclosure, a silicon substrate is provided having a p-type silicon base and an n-type silicon layer. An antireflective coating is formed on the n-type silicon layer. A a trench is formed in the antireflective coating so as to expose the n-type silicon layer in said trench. A reactive metal is placed in contact with said n-type silicon layer exposed within said trench, and a non-reactive metal is placed in contact with the reactive metal. The silicon substrate, reactive metal and non-reactive metal are fired to form a low Shottky barrier height contact to the n-type silicon layer and a conductive metal electrode in contact with the low Shottky barrier height contact. The low Shottky barrier height contact is comprised of one or more transition metal silicides, rare earth metal silicides, or combinations thereof.

As an alternative to the above method, a reactive metal is placed in contact with said n-type silicon layer exposed within the trench and the silicon substrate and reactive metal are fired to form a low Shottky barrier height contact to said n-type silicon layer. The low Shottky barrier height contact is comprised of one or more transition metal silicides, rare earth metal silicides, or combinations thereof. A non-reactive metal is subsequently deposited on to the metal silicide by a variety of means such as plating, thick film deposition or sputtering and the like.

In one embodiment, the transition metal silicides and rare earth metal silicides have the formula MₓSi_{y}, or RE Si₂ where M is a transition metal, RE is a rare earth metal, Si is silicon, x can vary from 1 to 5 and therebetween, and y can vary from 1 to 3 and therebetween. Perfect stoichiometry is not a requirement so x and y, for example, in M₁Si₁ can be slightly less than 1 or slightly more than 1. The transition metal silicide or rare earth silicide is preferably chosen from the silicides of titanium, tantalum, vanadium, zirconium, hafnium, niobium, chromium, nickel, molybenem, cobalt, tungsten, cerium, dysprosium, erbium, holmium, gadolinium, lanthanum, and scandium, yttrium and combinations thereof. Metal silicides that can be utilized include Ti₅Si₃, TiSi, TiSi₂, Ta₂Si, Ta₅Si₃, TaSi₂, V₃Si, V₅Si₃, ViSi₂, Zr₄Si, Zr₂Si, Zr₅Si₃, Zr₄Si₃, Zr₆Si₅, ZrSi, ZrSi₂, HfSi, HfSi₂, Nb₄Si, Nb₅Si₃, NbSi₂, CrSi₂, NiSi, Ni₂Si, Ni₃Si, Ni₃Si₂, NiSi₂, Mo₃Si₂, Mo₃Si MoSi₂, CoSi, Co₂Si, Co₃Si, CoSi₂, W₃Si₂ WSi₂, CeSi₂, DySi₂, ErSi₂, HoSi₂, GdSi₂, LaSi₂, ScSi₂ and YSi₂.

A thick film composition for producing a photovoltaic cell is also disclosed. The composition includes one or more metals that react with silicon to form a stable silicide, including metals selected from the group of from titanium, zirconium, hafnium, vanadium, niobium, tantalum, molybdenum, cobalt, nickel, cerium, dysprosium, erbium, holmium, gadolinium, lanthanum, scandium, yttrium and combinations thereof. The composition may also includes one or metals that do not form stable silicides with silicon selected from the group of silver, tin, bismuth, lead, antimony, zinc, germanium, phosphorus, gold, cadmium, berrylium, and combinations thereof. In one embodiment, the reactive and non-reactive metals of the composition are in the form of particles having an average diameter in the range of 100 nanometers to 50 micrometers, and more preferably 500 nonometers to 50 micrometers. In a preferred embodiment, the reactive metal forms between 1 and 25 weight percent of the total of the metals composition. A silicon solar cell may be formed having front face electrodes formed from this thick film composition.

Those skilled in the art will appreciate the above stated advantages and benefits of the invention upon reading the following detailed description of the embodiments.

### BRIEF DESCRIPTION OF THE DRAWINGS

FIG. 1 is a process flow diagram illustrating the fabrication of a semiconductor device according to a conventional process wherein the silicon nitride ARC has been locally removed.

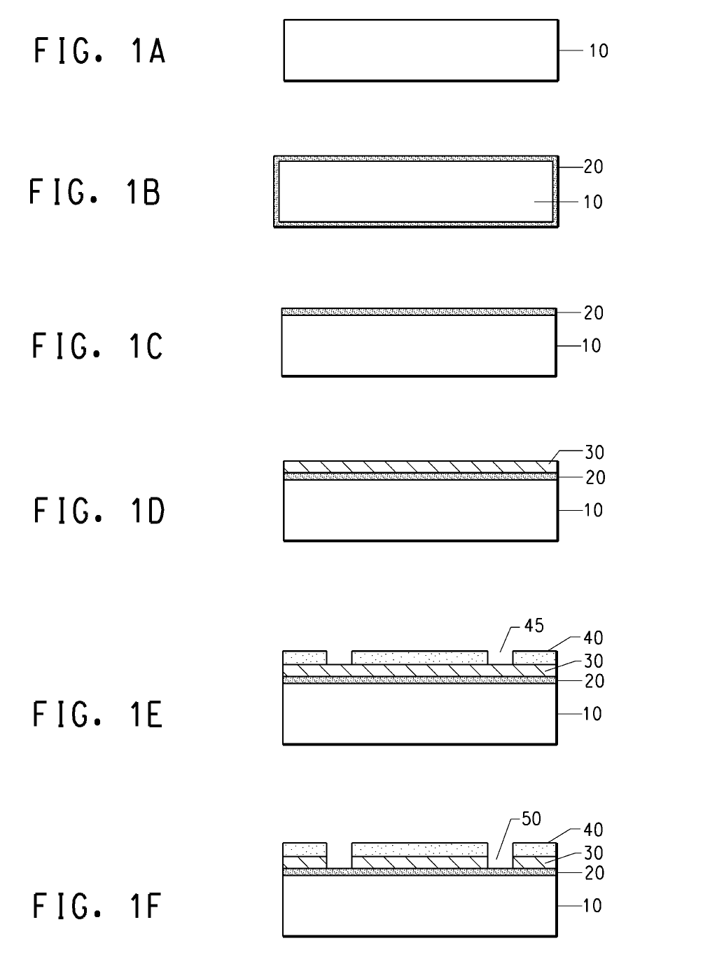

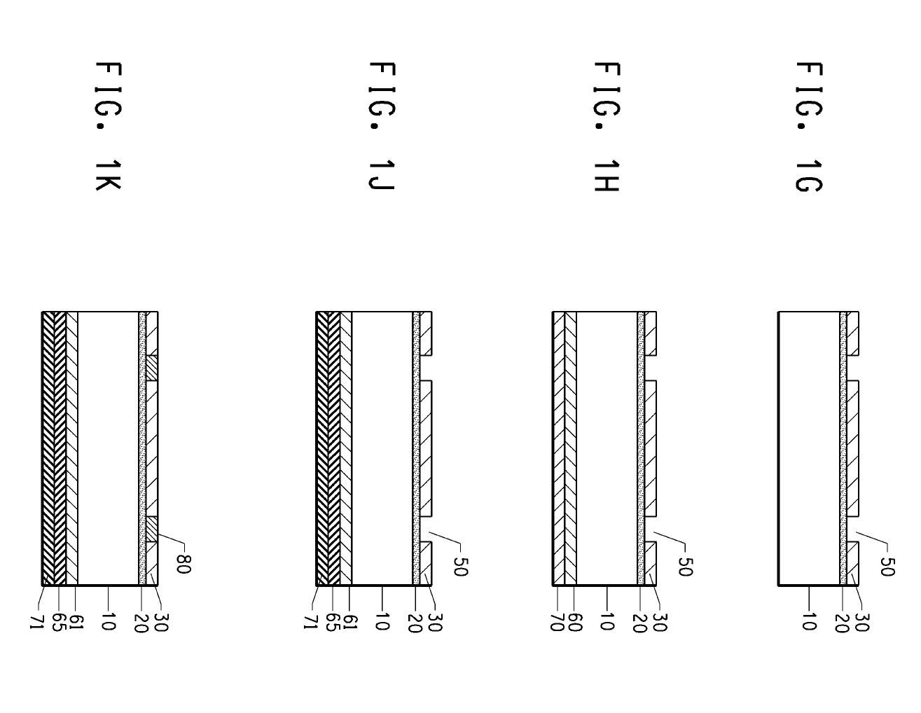

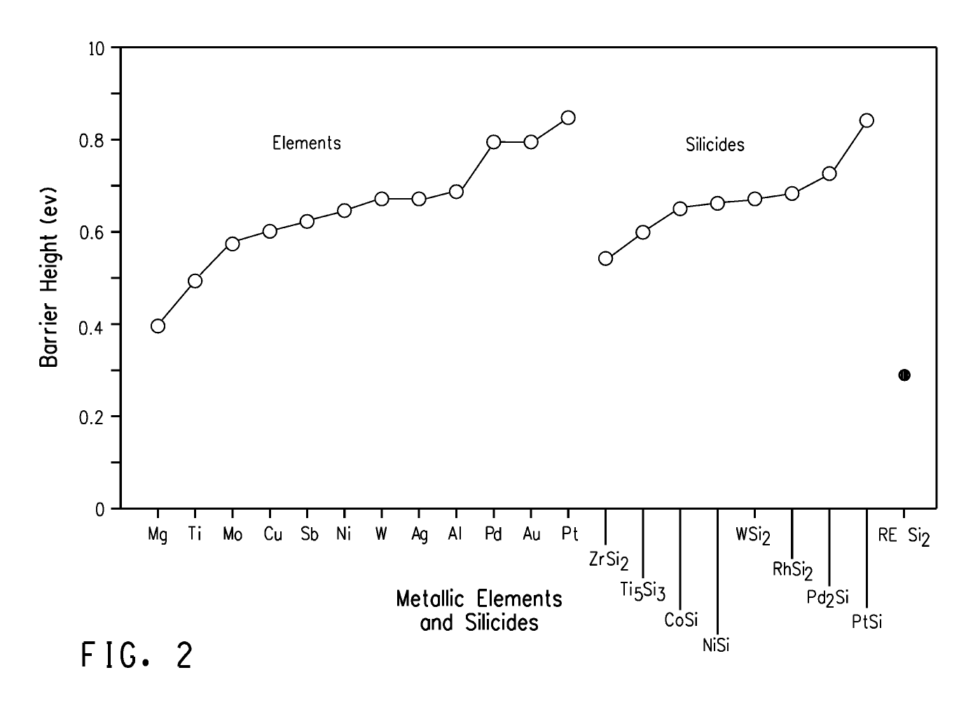

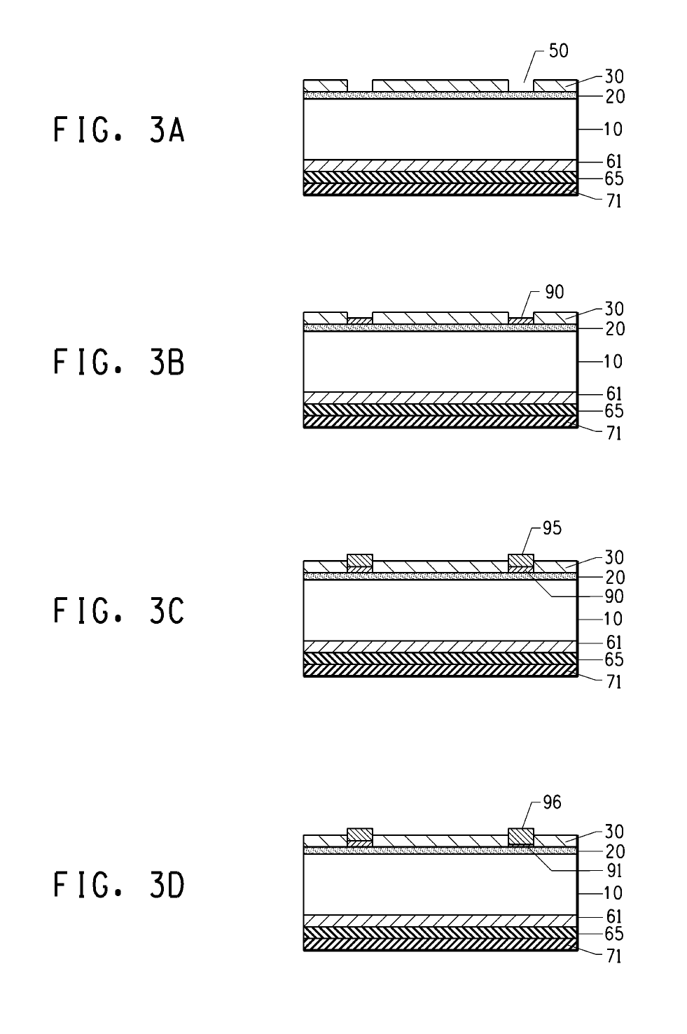

Reference numerals shown in FIG. 1 are explained below.
10: p-type silicon substrate
20: n-type diffusion layer
30: anti-reflective coating
40: photoresist on the anti-reflective coating
45: trench in the photoresist exposing the underlying anti-reflective coating
50: trench in the anti-reflective coating exposing the n-type silicon
60: aluminum paste formed on backside
70: silver or silver/aluminum paste formed on backside
61: p+ layer (back surface field, BSF)
65: aluminum back electrode (obtained by firing back side aluminum paste)
71: silver or silver/aluminum back electrode (obtained by firing back side silver paste)
80: metal composition deposited into trench

FIG. 2 shows Shottky barrier heights of various metals and silicides to n-type silicon.

FIG. 3 shows a process flow diagram, shown in side elevation, illustrating the fabrication of a silicon solar cell according to the present invention.

### DETAILED DESCRIPTION OF THE INVENTION

Photovoltaic devices having a low Shottky barrier height electrode contact to n-type silicon are disclosed. Also disclosed are methods for making photovoltaic devices having a low Shottky barrier height electrode contact to n-type silicon. The disclosed photovoltaic devices are solar cells but they may also be other photovoltaic devices having electrode contacts to n-type silicon such as photodetectors or light emitting diodes. The disclosed embodiment is a solar cell with a front face electrode on n-type silicon having a low Shottky barrier height electrode contact comprised of silicides comprising one or more transition metals or rare earth metals.

As used herein, the term “reactive metal” refers to a metal or mixtures of metals that reacts with silicon on firing to a form a stable highly conductive metal silicide. Such metals may include metals or mixtures thereof from titanium (Ti), zirconium (Zr), hafnium (Hf), tantalum (Ta), niobium (Nb) vanadium (V), chromium, (Cr), molybdenum, (Mo), cobalt (Co), nickel, (Ni), cerium (Ce), dysprosium (Dy), erbium (Er), holmium (Ho), gadolinium (Gd), lanthanum (La) and other rare earth metals such as yttrium (Y). Each of these reactive metals will react with silicon to form a highly conducting metal silicide with low Shottky barrier height contacts to n-type silicon.

As used herein, the term “non-reactive metal” refers to a metal or mixture of metals that do not form stable conductive silicides with silicon even though they may form high temperature eutectic compositions with silicon, such as that observed with silver. The non-reactive metals may be chosen from, but not limited to, the group of silver (Ag), tin (Sn), bismuth (Bi), lead (Pb), antimony (Sb), zinc (Zn), germanium (Ge), phosphorus (P), gold (Au), cadmium (Cd), and berrylium (Be). Other metals with high melting points, such as palladium (Pd), may be included in small quantities to achieve other specific properties. The non-reactive metals do not include boron (B), aluminum (Al), gallium (Ga), indium (In), and thallium (TI) as they may acceptor dope the n-type silicon and raise its surface resistivity too high.

According to the disclosed method, low Shottky barrier height metal silicide contacts are formed from the reaction of the silicon with a reactive metal during firing. It is desirable that the silicide formation does not consume much of the n-type silicon to avoid penetration and damage to the p-n junction. The silicides so formed, therefore, may be a few nanometers to approximately 100 nanometers in thickness.

In a preferred embodiment, an additional non-reactive metal layer of a low resistance is formed in contact with the low Shottky barrier height contact in order to carry current to outside circuitry. The non-reactive metal does not alter the silicon substrate.

In the case of thin film contacts, the non-reactive metal layer or electrode may be accomplished by depositing a non-reactive metal layer over the reactive metal layer prior to the firing process. In one preferred embodiment, the reactive metal and non-reactive metal are co-deposited on the silicon substrate. In another thin film embodiment, the reactive metal is deposited on the silicon and fired before the non-reactive metal is deposited over the reacted silicide formed from the previously deposited reactive metal and the silicon. Alternatively, the non-reactive metal may be deposited after firing over the metal silicide by a variety of means such as plating, thick film deposition or sputtering and the like.

In the case of a thick film deposition method, a non-reactive metal paste may be deposited over a reactive metal paste prior to the firing process. Alternatively, the reactive metal paste may be deposited on the silicon substrate and fired prior to the deposition of a non-reactive metal paste. In another preferred embodiment, the non-reactive metal paste composition is mixed with a reactive metal paste composition in the desireable quantities so that a single deposition process can be made.

Another alternative approach would be to alloy the reactive metal with the non-reactive metal to form a reactive metal alloy for deposition by thin or thick film processes. The amount of reactive metal in such an alloy composition is between 1 and 25 weight % of the total metal in the composition.

Upon deposition and firing, the reactive metal reacts with the silicon to form one or more highly conductive transition metal silicide or rare earth metal silicide. The metal silicides have the formula MₓSi_{y}, or RE Si₂ wherein M is a transition metal, RE is a rare earth metal, Si is silicon, x can vary from 1 to 5 and therebetween, and y can vary from 1 to 3 and therebetween. Perfect stoichiometry is not a requirement so x and y, for example, in M₁Si₁ can be slightly less than 1 or slightly more than 1. The transition metal silicide or rare earth silicide is preferably chosen from the silicides of titanium, tantalum, vanadium, zirconium, hafnium, niobium, chromium, tungsten, nickel, molybenem, cobalt, tungsten, cerium, dysprosium, erbium, holmium, gadolinium, lanthanum, scandium, and yttrium and combinations thereof. Metal silicides that can be utilized include Ti₅Si₃, TiSi, TiSi₂, Ta₂Si, Ta₅Si₃, TaSi₂, V₃Si, V₅Si₃, ViSi₂, Zr₄Si, Zr₂Si, Zr₅Si₃, Zr₄Si₃, Zr₆Si₅, ZrSi, ZrSi₂, HfSi, HfSi₂, Nb₄Si, Nb₅Si₃, NbSi₂, CrSi₂, NiSi, Ni₂Si, Ni₃Si, Ni₃Si₂, NiSi₂, Mo₃Si₂, Mo₃Si MoSi₂, CoSi, Co₂Si, Co₃Si, CoSi₂, W₃Si₂ WSi₂, CeSi₂, DySi₂, ErSi₂, HoSi₂, GdSi₂, LaSi₂, ScSi₂, and YSi₂.

As shown in FIG. 2 (adapted from “Barrier Heights to n-Silicon”, Andrews et al., J. Vac. Sci. Tech 11, 6, 972, 1974), the Shottky barrier height values of their contacts to n-type silicon for the metal silicides of titanium and zirconium, for example, are approximately 0.55 eV and those for the rare earth disilicides (RE Si₂) are in the order of ˜0.3 eV. It can be seen in FIG. 2 that these metal silicides can form lower Shottky barrier height contacts to n-type silicon than is the case for silver or nickel metal, the conventional materials used for contacts with n-type silicon in photovoltaic devices such as solar cells. An advantage of such metal silicides is that they are very amenable to being coated by additional metal, by solder reflow, plating, or other deposition techniques, to form an electrode such as the final front face electrode of a silicon solar cell. Depostion of the non-reactive metal can also be accomplished by atomic layer deposition, sputtering, chemical vapor deposition, molecular beam epitaxy, pulsed laser desposition, or thick film deposition processes such as screen printing and the like.

The non-reactive metal or mixture of metals are chosen to have relatively low electrical resistivities. It is also preferred that the non-reactive metals have melting points close to or even less than the peak firing temperature. Metal compositions may be designed with multiple elements to achieve the desired melting point by use of eutectic compositions, for example. The metal mixture may also have antimony (Sb), arsenic (As), and/or bismuth (Bi) as they may additionally act as donor dopants to locally selectively dope the silicon under the paste during firing to reduce the surface resistivity and improve the contact resistance. Phosphorus (P), may also be included, even though it is not a metal.

### Deposition Methods

The reactive metals and non-reactive metals described above may be deposited on the silicon substrate by thin film processes or thick film processes or by other methods. Thin film processes include, but are not limited to, sputtering, metal evaporation, chemical vapor deposition, atomic layer deposition, pulsed laser deposition, and the like. The metals are deposited in their elemental state and may be deposited as separate layers or co-deposited to form mixtures or alloys.

The metals may also be deposited by thick film processes. Thick film processes include screen printing, ink jet printing, or photo-imaging techniques, for example. Screen printing is advantageous in that it is a cost effective process. In this case, a paste containing the above metals in powder form is printed through a screen in a desired pattern on the surface of the silicon.

Suitable powders for use in thick film compositions made from reactive metals should be as free of oxide as possible so that the above reaction is not hindered by native oxides of the reactive metals. Because reactive metals automatically form oxides in air to a predetermined thickness due to their oxidation characteristics, the larger the size of the powers, the lower the total oxide content. Firing the powders in a reducing atmosphere will prevent further substantial oxidation but atmospheres have to be extremely reducing to reduce the oxides of reactive metals to the metal. Therefore, it is preferable to use powders with the largest particle size consistent with good thick film paste making properties to minimize the oxide level. For optimum thick film paste properties, such powders should be between approximately 100 nanometers to approximately 50 micrometers in size, and more preferably in the range of 500 nanometers to 50 micormeters.

Suitable powders for thick film compositions made from non-reactive metals should also be as free of oxide as possible. Such powders, particularly those with a small negative free energy of formation of their oxides, or noble metals, may be smaller in size than reactive metals as the oxides may be reduced to the metal by the reducing atmosphere during the firing process or they may not form oxides. However, nonreactive metals with a high negative free energy of oxide formation should have low oxygen content and hence larger particle sizes.

For thick film deposition, the metal powders described above are typically mixed with an organic medium by mechanical mixing to form viscous compositions called “pastes”, having suitable consistency and rheology for printing. The organic medium is a fugitive material, in that it is burnt off during the initial firing process. A wide variety of inert viscous materials can be used as the organic medium. The organic medium must be one in which the metal powders are dispersible with an adequate degree of stability. The rheological properties of the medium must be such that they lend good application properties to the composition, including: stable dispersion of metal powders, appropriate viscosity and thixotropy for screen printing, appropriate paste wettability of the substrate, and a good drying rate. The organic vehicle used in the thick film composition of the present invention is preferably a nonaqueous inert liquid. Use can be made of any of various organic vehicles, which may or may not contain thickeners, stabilizers and/or other common additives. The organic medium is typically a solution of polymer(s) in solvent(s). Additionally, a small amount of additives, such as surfactants, may be a part of the organic medium. The most frequently used polymer for this purpose is ethyl cellulose. Other examples of polymers include ethylhydroxyethyl cellulose, wood rosin, mixtures of ethyl cellulose and phenolic resins, polymethacrylates of lower alcohols, and monobutyl ether of ethylene glycol monoacetate can also be used. The most widely used solvents found in thick film compositions are ester alcohols and terpenes such as alpha- or beta-terpineol or mixtures thereof with other solvents such as kerosene, dibutylphthalate, butyl carbitol, butyl carbitol acetate, hexylene glycol and high boiling alcohols and alcohol esters. In addition, volatile liquids for promoting rapid hardening after application on the substrate can be included in the vehicle. Various combinations of these and other solvents are formulated to obtain the viscosity and volatility requirements desired.

The polymer present in the organic medium is in the range of 1 wt. % to 11 wt. % of the total composition. The thick film composition of the present invention may be adjusted to a predetermined, screen-printable viscosity with the organic medium. The ratio of organic medium in the thick film composition to the inorganic components in the dispersion is dependent on the method of applying the paste and the kind of organic medium used, and it can vary. Usually, the dispersion will contain 70-95 wt % of inorganic components and 5-30 weight % of organic medium (vehicle) in order to obtain good wetting.

A solar cell having low Shottky barrier height electrode contacts as described herein may be manufactured by the following methods.

Referring to FIG. 3, the article as shown in FIG. 3A is provided. The article may comprise single-crystal silicon or multicrystalline silicon, and includes a p-type silicon substrate 10, an n-type diffusion layer 20, an anti-reflective coating 30, and a trench 50 in the anti-reflective coating exposing the n-type silicon layer. Optionally, the device may have a backside with a p+ layer 61 (back surface field, BSF), an aluminum back electrode 65 (obtained by firing back side aluminum paste) and a silver or silver/aluminum back electrode 71 (obtained by firing back side silver paste). The article shown in FIG. 3A may be prepared as described above with regard to the article shown in FIG. 1J.

The reactive metal as described herein is now deposited into the trench 50 of FIG. 3A to form the reactive metal layer 90 of FIG. 3B. The reactive metal 90 is deposited through a screen or mask conforming to the dimensions and shape of the trench 50. The thickness of the reactive metal layer 90 is selected to be thick enough to form a reactively bonded silicide interfacial layer when subjected to the elevated temperature of firing but not thick enough to penetrate deep into the n-type silicon and cause damage to the p-n junction.

The non-reactive metal may be next deposited on the reactive metal to form the non-reactive metal layer 95 of FIG. 3C. An alternative approach is to co-deposit the reactive metal 90 and non-reactive metal 95 in appropriate proportions either as a mixture or as an alloy to form a single deposit. The advantage of a single metal deposit is that the reactive metal portion of the mix or alloy can be controlled to low amounts so that the formed silicide layer is thin and controlled.

The deposited composition(s) are now fired. Firing is typically accomplished in a furnace at a temperature within the range of 400° C. to 975° C., the actual temperature depending upon the metal composition and the extent of reaction desired. Firing at a temperature at the lower end of this range may be preferred because oxidation issues will be much reduced. Firing is typically undertaken in a reducing atmosphere that may comprise vacuum, pure nitrogen, a mixture of hydrogen and nitrogen or mixtures of other gases such as argon, carbon monoxide, carbon dioxide, and/or water. Such gas mixtures may be used to control the partial pressure of oxygen during the firing process to avoid oxidation of the metals. The exact partial pressure of oxygen (PO₂) required to prevent oxidation is dependent on the metal compositions. Atmospheres that fully protect the metals from oxidation can be thermodynamically derived from standard free energy of formation of oxides as a function of temperature calculations or diagrams as disclosed in “F. D. Richardson and J. H. E Jeffes, J. Iron Steel Inst., 160, 261 (1948)”. In general, however, a partial pressure of oxygen (PO₂) of between approximately 10⁻⁶ to 10⁻¹⁸ atmospheres is suitable. This can be generally accomplished by the use of argon, nitrogen, forming gas (1-4% hydrogen in nitrogen), a mixture of hydrogen and argon, or vacuum. Use of argon may be advantageous as it precludes any reaction between the reactive metal and nitrogen. Such an atmosphere may not completely protect the reactive metals from oxidation but the rate of oxidation will be severly depressed and will not impede the transformation reaction.

It is feasible to form a molten metal alloy in the firing process. A molten metal allows for a reduction in the silicide formation temperature due to an acceleration of the kinetics of the reaction via assistance of the liquid phase. In the case wherein the reactive metal is deposited first followed by the the non-reactive metal or both metals are deposited as a mixture, the non-reactive metal melts and rapidly dissolves the reactive metal forming a molten alloy. In the case of a deposited alloy, the metal melts to form the molten alloy. While the metal is molten, the reactive metal preferentially migrates through the molten metal to the silicon interface and reacts with the silicon to form the reactive metal silicide. As the reactive metal is depleted at the interface, more reactive metal migrates to the interface to react. This continues until either the reactive metal in the molten alloy is consumed in forming the silicide or the reaction is terminated by cessation of the firing process. Reactive metal silicides are very amenable to being wetted by molten metals so that during the molten stage, the molten metal forms a coherent film over the surface of the silicide. Referring to FIG. 3D, the firing process forms an electrode comprising a thin reactively bonded, conductive reactive metal silicide first layer 91 formed on the underlying n-type silicon 20 and a low resistivity metal second layer 96 formed over the reactive metal silicide first layer 91.

While it is feasible to form a molten reactive metal alloy in the firing process, it is entirely feasible that the firing does not need to melt the non-reactive metal and the transformation process occurs in the solid state. It is also feasible that the process steps described herein may be modified so that the reactive metal is fired first followed by a separate deposition of a non-reactive metal. It is also further feasible that the process steps described herein may be modified in their order so that the novel composition(s) described herein may be co-fired with the backside pastes of the solar cell.

What is claimed is:

1. A method for making a photovoltaic device, comprising:
providing a silicon substrate having an n-type silicon layer;
placing a reactive metal in contact with said n-type silicon layer,
firing said silicon substrate and reactive metal to form a low Shottky barrier height contact to said n-type silicon layer, said low Shottky barrier height contact comprised of one or more transition metal silicides, rare earth metal silicides, or combinations thereof, and
forming a conductive metal electrode in contact with said low Shottky barrier height contact.

2. The method of claim 1, wherein a non-reactive metal is plased in contact with said reactive metal before said silicon substrate and reactive metal are fired, and wherein said non-reactive metal forms the conductive metal electrode in contact with said low Shottky barrier height contact.

3. The method of claim 1, wherein a non-reactive metal is placed in contact with said a low Shottky barrier height contact after said silicon substrate and reactive metal are fired.

4. The method of claim 1, wherein the reactive metal is from a transition metal or rare earth metal selected from titanium, zirconium, hafnium, vanadium, niobium, tantalum, molybdenum, tungsten, cobalt, nickel, cerium, dysprosium, erbium, holmium, gadolinium, lanthanum, scandium, yttrium and combinations thereof.

5. The method of claim 2, wherein the non-reactive metal is selected from the group of silver, tin, bismuth, lead, antimony, zinc, germanium, phosphorus, gold, cadmium, berrylium, and combinations thereof.

6. The method of claim 2, wherein reactive metal and the non-reactive metal are combined to form a metals composition, and said metals composition is subsequently deposited on said n-type silicon layer.

7. The method of claim 6, wherein the reactive metal of is in the form of particles having an average diameter in the range of 100 nanometers to 50 micrometers.

8. The method of claim 6, wherein the reactive metal forms between 1 and 25 weight percent of the total metals in said metals composition.

9. The method of claim 2, wherein said silicon substrate, reactive metal and non-reactive metal are fired at a temperature between 400° C. and 950° C.

10. The method of claim 3, wherein said silicon substrate and reactive metal are fired at a temperature between 400° C. and 950° C.

11. A method for making a silicon solar cell, comprising:
providing a silicon substrate having a p-type silicon base and an n-type silicon layer;
forming an antireflective coating on said n-type silicon layer;
forming a trench in said antireflective coating so as to expose said n-type silicon layer in said trench;
placing a reactive metal in contact with said n-type silicon layer exposed within said trench;
placing a non-reactive metal in contact with said reactive metal;
firing said silicon substrate, reactive metal and non-reactive metal to form a low Shottky barrier height contact to said n-type silicon layer and a conductive metal electrode in contact with said low Shottky barrier height contact, said low Shottky barrier height contact comprised of one or more transition metal silicides, rare earth metal silicides, or combinations thereof.

12. The method of claim 11, wherein the reactive metal is selected from the group of from titanium, zirconium, hafnium, vanadium, niobium, tantalum, molybdenum, cobalt, chromium, tungsten, nickel, cerium, dysprosium, erbium, holmium, gadolinium, lanthanum, scandium, yttrium and combinations thereof.

13. The method of claim 11, wherein the non-reactive metal is selected from the group of silver, tin, bismuth, lead, antimony, zinc, germanium, phosphorus, gold, cadmium, berrylium, and combinations thereof.

14. The method of claim 11, wherein the transition metal silicides and rare earth metal silicides have the formula MₓSi_{y}, or RE Si₂ wherein M is a transition metal, RE is a rare earth metal, Si is silicon, x is in the range of from 1 to 5, and y is in the range of from 1 to 3.

15. The method of claim 14 wherein the transition metal silicides and rare earth metal silicides are selected from Ti₅Si₃, TiSi, TiSi₂, Ta₂Si, Ta₅Si₃, TaSi₂, V₃Si, V₅Si₃, ViSi₂, Zr₄Si, Zr₂Si, Zr₅Si₃, Zr₄Si₃, Zr₆Si₅, ZrSi, ZrSi₂, HfSi, HfSi₂, Nb₄Si, Nb₅Si₃, NbSi₂, CrSi₂, NiSi, Ni₂Si, Ni₃Si, Ni₃Si₂, NiSi₂, Mo₃Si₂, Mo₃Si MoSi₂, CoSi, Co₂Si, Co₃Si, CoSi₂, W₃Si₂ WSi₂, CeSi₂, DySi₂, ErSi₂, HoSi₂, GdSi₂, LaSi₂, and YSi₂ and combinations thereof.

16. A thick film composition for producing a photovoltaic cell, comprising:
one or more reactive metals that react with silicon to form stable conductive silicides, said reactive metals being selected from the group of from titanium, zirconium, hafnium, vanadium, niobium, tantalum, molybdenum, cobalt, nickel, chromium, tungsten, cerium, dysprosium, erbium, holmium, gadolinium, lanthanum, scandium, yttrium and combinations thereof;
one or more non-reactive metals that do not react with silicon to form stable silicides, said non-reactive metals being selected from the group of silver, tin, bismuth, lead, antimony, zinc, germanium, phosphorus, gold, magnesium, cadmium, berrylium, tellurium, and combinations thereof;
wherein said reactive and non-reactive metals are in the form of particles having an average diameter in the range of 100 nanometers to 50 micrometers.

17. The thick film composition of claim 16 wherein the reactive metal forms between 1 and 25 weight percent of the total metals in said metals composition.

18. A silicon solar cell having front face electrodes formed from the composition of claim 16.

19. A photovoltaic device made by the process of claim 1.

20. A silicon solar cell made by the process of claim 11.
